(19) United States
(12) Patent Application Publication
(10) Pub. No.: US 2009/0176321 A1
(43) Pub. Date: Jul. 9, 2009

(54) TEMPLATE FOR FORMING SOLDER BUMPS, METHOD OF MANUFACTURING THE TEMPLATE AND METHOD OF INSPECTING SOLDER BUMPS USING THE TEMPLATE

(76) Inventor: Pil-Gyu Park, Cheonan-si (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/105,550

(22) Filed: Apr. 18, 2008

(30) Foreign Application Priority Data
Jan. 7, 2008 (KR) 10-2008-0001790

(51) Int. Cl. H01L 21/66; H01L 21/44

(52) U.S. Cl. 438/16; 438/613; 257/E21.529; 257/E21.294

(57) ABSTRACT

A template for forming solder bumps includes a transparent substrate on which a plurality of cavities is formed at an upper surface portion thereof, and a light-reflective layer and a protective layer formed on a lower surface of the transparent substrate. When a nozzle makes close contact with the template to inject a molten solder into the cavities, damage to the template may be prevented by the light-reflective layer and the protective layer, and thus the lifetime of the template may be increased. An inspection process on the solder bumps, which are formed in the cavities of the template, may be easily performed by analyzing light reflected by the light-reflective layer.

### CROSS-REFERENCE TO RELATED APPLICATIONS

This application claims priority under 35 U.S.C. §119 to Korean Patent Application No. 2008-1790, filed on Jan. 7, 2008 in the Korean Intellectual Property Office (KIPO), the contents of which are incorporated herein by reference in their entirety.

### BACKGROUND OF THE INVENTION

1. Field of the Invention

The present invention relates to a template for forming solder bumps, a method of manufacturing the template and a method of inspecting solder bumps using the template. More particularly, the present invention relates to a template having cavities to form solder bumps in a microelectronic packaging technology, a method of manufacturing the template and a method of inspecting solder bumps formed in the cavities of the template.

2. Description of the Related Art

Recently, a microelectronic packaging technology is increasingly moving from wire bonds to solder bumps as the method of interconnection. There are various solder bumping technologies used in volume production. For example, these include electroplating, solder paste printing, evaporation, the direct attachment of preformed solder spheres, and the like.

Particularly, a C4NP (controlled collapse chip connection new process) technology has lately attracted considerable attention by enabling fine pitch bumping at low cost and improving reliability of semiconductor devices. Examples of the C4NP technology are disclosed in U.S. Pat. Nos. 5,607,099, 5,775,569, 6,025,258, etc.

According to the C4NP technology, spherical solder bumps are formed in cavities of a template and then transferred onto bump pads of a semiconductor wafer at a reflow temperature of the solder bumps. The bump pads are connected with metal wires of chips formed on the semiconductor substrate, and under-bump metallurgy (UBM) pads are disposed on the bump pads. The UBM pads may be provided to improve an adhesive strength between the solder bumps and the bump pads.

The semiconductor chips of the wafer, onto which the solder bumps are transferred, may be individualized by a dicing process. Each of the semiconductor chips may be attached to a substrate, for example, a printed circuit board (PCB), by a solder reflow process and an underfill process to thereby manufacture a flip chip device.

A molten solder may be injected into the cavities of the template to form the solder bumps. An example of an apparatus for injecting a molten solder is disclosed in U.S. Pat. No. 6,231,333. The injected solder may be solidified in the cavities, and the template may be heated to a solder reflow temperature to form spherical solder bumps.

FIG. 1 is a cross-sectional view illustrating a conventional template for forming solder bumps.

Referring to FIG. 1, a plurality of cavities 14 is formed at surface portions of a template 10 to form solder bumps. The cavities 14 may be formed by a wet etching process. Particularly, a mask may be formed on a substrate 12 to have a plurality of openings and a wet etching process may then be performed using the mask to thereby form the cavities 14. An example of a method of forming the cavities 14 is disclosed in U.S. Pat. No. 6,332,569.

It is difficult to use the conventional template 10 for many hours because the template 10 is formed of silicon oxide. Particularly, a nozzle for providing a molten solder makes close contact with the template 10 and the molten solder is injected into the cavities 14 by a relative sliding movement between the nozzle and the template 10. Thus, the template 10 may be damaged by the nozzle while injecting the molten solder. Further, the template 10 may be easily broken during its transfer.

### SUMMARY OF THE INVENTION

Example embodiments of the present invention provide a template having increased lifetime.

Further, example embodiments of the present invention provide a method of manufacturing the template as mentioned above.

Still further, example embodiments of the present invention provide a method of inspecting solder bumps formed in cavities of the template as mentioned above.

According to an aspect of the present invention, a template may include a transparent substrate on which a plurality of cavities is formed at upper surface portions thereof, and a light-reflective layer formed on a lower surface of the transparent substrate.

In some example embodiments of the present invention, the light-reflective layer may include metal, and a protective layer may be formed on the light-reflective layer.

In a method of manufacturing a template according to another aspect of the present invention, a light-reflective layer may be formed on a lower surface of a transparent substrate, and upper surface portions of the transparent substrate may be partially removed to form a plurality of cavities to be used to form solder bumps, thereby forming the template.

In a method of inspecting solder bumps according to still another aspect of the present invention, the solder bumps may be formed in cavities of a template. The cavities may be formed at upper surface portions of a transparent substrate, and a light-reflective layer may be formed on a lower surface of the transparent substrate. Light may be irradiated toward an upper surface of the transparent substrate. The light may be reflected by the light-reflective layer and may be detected by a detector. The detected light may be analyzed to ascertain whether the solder bumps are normally formed in the cavities.

In some example embodiments of the present invention, an image of the solder bumps may be acquired from the detected light, and it is ascertained whether the solder bumps are normally formed in the cavities from regularities of the image.

In some example embodiments of the present invention, an intensity profile may be acquired from the detected light, and it is ascertained whether the solder bumps are normally formed in the cavities from variation in distances between peak values in the intensity profile of the detected light.

According to the example embodiments of the present invention, a template for forming solder bumps may include a transparent substrate, on which a plurality of cavities is formed at upper surface portions thereof, and a light-reflective layer formed on a lower surface of the transparent substrate. Thus, even though the template makes close contact with a nozzle to inject a molten solder into the cavities, damage to the template may be prevented, thereby increasing the lifetime of the template. Further, an inspection process on the solder bumps, which are formed in the cavities, may be easily performed by analyzing light reflected by the light-reflective layer.

### BRIEF DESCRIPTION OF THE DRAWINGS

Example embodiments of the present invention will become readily apparent along with the following detailed description when considered in conjunction with the accompanying drawings, wherein:

FIG. 1 is a cross-sectional view illustrating a conventional template for forming solder bumps;

FIG. 2 is a cross-sectional view illustrating a template for forming solder bumps in accordance with an example embodiment of the present invention;

FIGS. 3 and 4 are cross-sectional views illustrating a method of manufacturing the template shown in FIG. 2;

FIGS. 5 to 7 are cross-sectional views illustrating a method of forming solder bumps in cavities of the template shown in FIG. 2; and

FIG. 8 is a schematic view illustrating a method of inspecting solder bumps formed in the cavities of the template shown in FIG. 2.

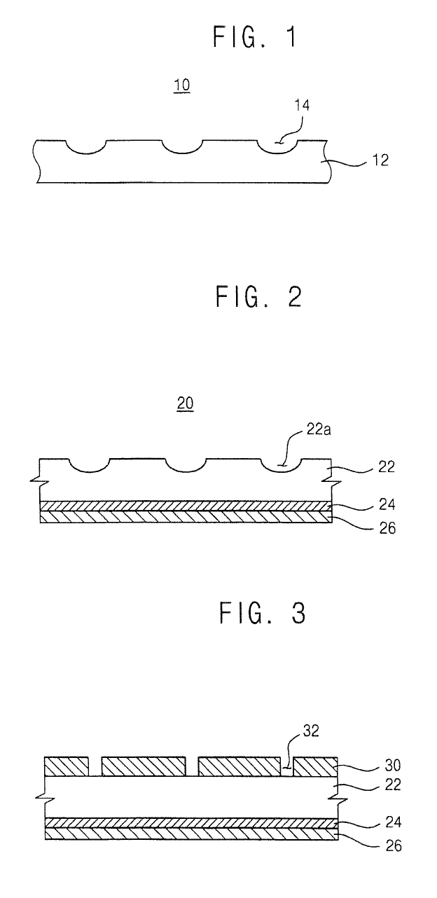

### DESCRIPTION OF THE EMBODIMENTS

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompass both an orientation of “lower” and “upper” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

FIG. 2 is a cross-sectional view illustrating a template for forming solder bumps in accordance with an example embodiment of the present invention.

Referring to FIG. 2, a template 20 for forming solder bumps may include a transparent substrate 22, a light-reflective layer 24 and a protective layer 26. A plurality of cavities 22a may be formed at an upper surface portion of the transparent substrate 22. The light-reflective layer 24 may be formed on a lower surface of the transparent substrate 22.

For example, the transparent substrate 22 may be a glass substrate formed of silicon oxide. Particularly, examples of the silicon oxide that may be used for the transparent substrate 22 may include borosilicate glass (BSG), phosphosilicate glass (PSG), borophosphosilicate glass (BPSG), and the like. These silicon oxides may be used alone or in a combination thereof.

The light-reflective layer 24 may include metal. Examples of the metal that may be used for the light-reflective layer 24 may include aluminum (Al), silver (Ag), tin (Sn), and the like. These metals may be used alone or in a combination thereof. Particularly, the light-reflective layer 24 may be formed by an electroplating process or a vacuum deposition process.

The protective layer 26 may be formed to protect the light-reflective layer 24 and may include metal or metal nitride. Examples of the metal that may be used for the protective layer 26 may include molybdenum (Mo), tungsten (W), titanium (Ti), copper (Cu), and the like. These metals may be used alone or in a combination thereof.

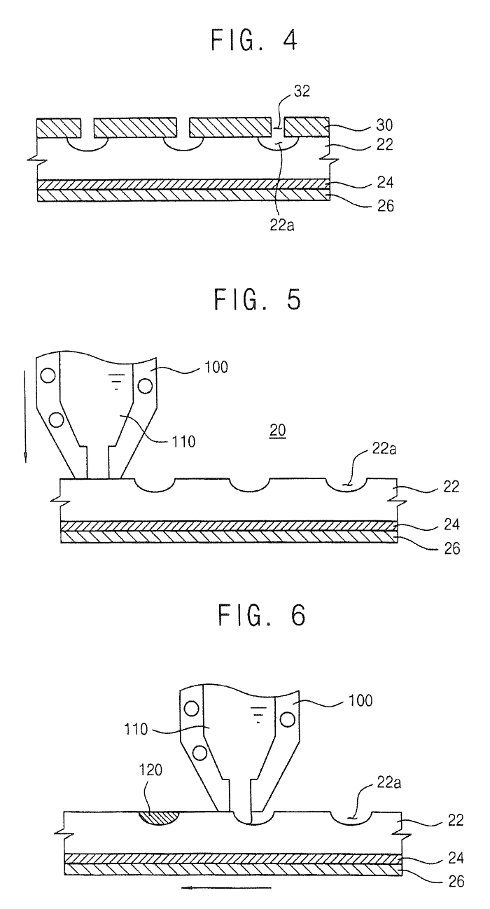

FIGS. 3 and 4 are cross-sectional views illustrating a method of manufacturing the template shown in FIG. 2.

Referring to FIG. 3, a light-reflective layer 24 and a protective layer 26 may be sequentially formed on a lower surface of a transparent substrate 22.

A mask layer (not shown) may be formed on an upper surface of the transparent substrate 22. A photoresist pattern may be formed on the mask layer. Examples of a material that may be used for the mask layer may include polysilicon, silicon nitride, and the like.

The mask layer may be patterned by an etching process using the photoresist pattern as an etching mask. As a result, an etching mask 30 having openings 32, which expose upper surface portions of the transparent substrate 22, may be formed on the upper surface of the transparent substrate 22.

The photoresist pattern may be formed by a photolithography process and may be removed by ashing and/or stripping processes after forming the etching mask 30.

Referring to FIG. 4, the upper surface portions of the transparent substrate 22 exposed by the openings 32 may be removed by an etching process using the etching mask 30. For example, the exposed upper surface portions of the transparent substrate 22 may be removed by a wet etching process using diluted hydrofluoric acid (DHF) to thereby form a plurality of cavities 22a at the upper surface portions of the transparent substrate 22.

The etching mask 30 may be removed by a wet etching process after forming the cavities 22a.

Solder bumps may be formed in the cavities 22a of a template manufactured by the method as described above. For example, a molten solder may be injected in the cavities 22a by using an injection nozzle and a solder reflow process may then be performed to thereby form the solder bumps.

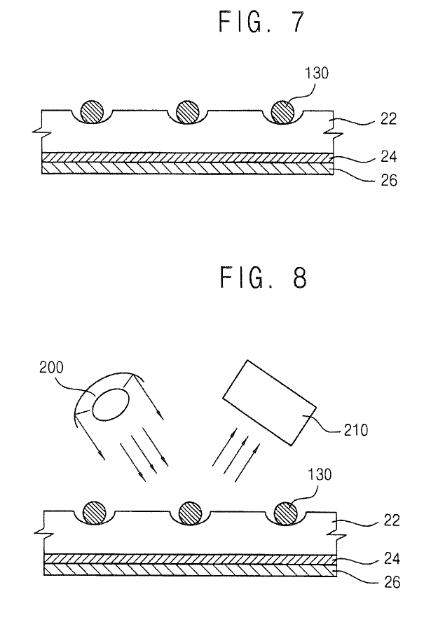

FIGS. 5 to 7 are cross-sectional views illustrating a method of forming solder bumps in the cavities of the template shown in FIG. 2.

Referring to FIGS. 5 to 7, a template 20 may be placed on a chuck (not shown). The template 20 may include a transparent substrate 22 on which a plurality of cavities 22a are formed at upper surface portions thereof, and a light-reflective layer 24 and a protective layer 26 formed on a lower surface of the transparent substrate 22.

A nozzle 100 may be disposed on an upper surface of the transparent substrate 22 to supply a molten solder 110 into the cavities 22a. Here, the nozzle 100 may be heated to a temperature equal to or higher than the melting point of a soldering material. The molten solder 110 may include tin (Sn), silver (Ag), copper (Cu), bismuth (Bi), indium (In), and the like. These materials may be used alone or in a combination thereof.

The template 20 may be heated to a temperature lower than the melting point of the soldering material. Particularly, the template 20 may be heated to a temperature lower than about 3° C. to about 10° C.; for example, about 5° C. lower than the melting point of the soldering material. When the template 20 is not sufficiently heated, the temperature of the nozzle 100, which is disposed on the template 20, may vary. On the contrary, when the template of the template 20 is excessively high, molten solders 120 injected in the cavities 22a may not be solidified.

After disposing the nozzle 100 to closely contact the upper surface of the template 20, the molten solder 110 may be sequentially injected into the cavities 22a of the template 20 by a relative sliding movement between the template 20 and the nozzle 100. Particularly, the molten solder 110 may be injected into the cavities 22a by a differential pressure between the interior and exterior of the nozzle 100. After injecting the molten solder 110 in the cavities 22a, the injected molten solder 120 may be solidified because the temperature of template 20 is lower than the melting point of the soldering material.

The strength of the template 20 may be sufficiently increased by the light-reflective layer 24 and the protective layer 26. Thus, even though the nozzle 100 makes close contact with the upper surface of the template 20 to inject the molten solder 110 into the cavities 22a, damage to the template 20 may be prevented. And further, the lifetime of the template 20 may be increased.

The solidified solders 120 in the cavities 22a may be melted by heating the template 20 to a solder reflow temperature, and spherical solder bumps 130 may be formed by surface tension.

After forming the solder bumps 130, an optical inspection process may be performed to ascertain whether the solder bumps 130 are normally formed in the cavities 22a.

FIG. 8 is a schematic view illustrating a method of inspecting solder bumps formed in the cavities of the template shown in FIG. 2.

Referring to FIG. 8, a light source 200 and a detector 210 may be disposed above a template 20 on which a plurality of solder bumps 130 is formed. The template 20 may include a transparent substrate 22 on which a plurality of cavities 22a is formed at upper surface portions thereof, and a light-reflective layer 24 and a protective layer 26 sequentially formed on a lower surface of the transparent substrate 22. The solder bumps 130 are formed in the cavities 22a. Examples of the light source 200 may include a light-emitting diode (LED), a mercury-vapor lamp, and the like.

Light irradiated from the light source 200 may pass through the transparent substrate 22 and may then be reflected by the light-reflective layer 24. The reflected light may be detected by the detector 210. The detector 210 may produce an image or an intensity profile from the detected light.

When the solder bumps 130 are normally formed in the cavities 22a, images of the solders 130 may be regularly arranged. However, when the solder bumps 130 are abnormally formed in the cavities 22a, for example, some solder bumps 130 are formed at positions apart from centers of the cavities 22a, the images of the solder bumps 130 may be irregularly arranged. That is, it may be ascertained whether the solder bumps are normally formed in the cavities 22a from regularities of the solder bumps 130 or variations in distances between the solder bumps 130.

Alternatively, it may be ascertained whether the solder bumps 130 are normally formed in the cavities 22a from the intensity profile of the detected light. Particularly, the intensity profile of the detected light may have peak values corresponding to the solder bumps 130, and the peak values may be spaced apart from one another at regular intervals. However, when the solder bumps 130 are abnormally formed, the peak values may be spaced apart from one another at irregular intervals.

As a result, it may be ascertained whether the solder bumps 130 are normally formed in the cavities 22a by analyzing the regularities in the image or the intensity profile of the detected light.

According to the example embodiments of the present invention as described above, a template for forming solder bumps may include a transparent substrate on which a plurality of cavities is formed at upper surface portions thereof, and a light-reflective layer and a protective layer formed on a lower surface of the transparent substrate. Thus, even though the template makes close contact with a nozzle to inject a molten solder in the cavities, damage to the template may be prevented, and further the lifetime of the template may be increased.

Moreover, an inspection process on the solder bumps, which are formed in the cavities, may be easily performed by analyzing light reflected from the light-reflective layer.

Although the example embodiments of the present invention have been described, it is understood that the present invention should not be limited to these example embodiments but various changes and modifications can be made by those skilled in the art within the spirit and scope of the present invention as hereinafter claimed.

What is claimed is:

1. A template for forming solder bumps comprising:
a transparent substrate on which a plurality of cavities is formed at upper surface portions thereof; and
a light-reflective layer formed on a lower surface of the transparent substrate.

2. The template of claim 1, wherein the light-reflective layer comprises metal.

3. The template of claim 1, further comprising a protective layer formed on the light-reflective layer.

4. A method of manufacturing a template comprising:
forming a light-reflective layer on a lower surface of a transparent substrate; and
partially removing upper surface portions of the transparent substrate to form a plurality of cavities to be used to form solder bumps.

5. The method of claim 4, further comprising forming a protective layer on the light-reflective layer.

6. A method of inspecting solder bumps formed using a template comprising a transparent substrate on which a plurality of cavities is formed at upper surface portions thereof, and a light-reflective layer formed on a lower surface of the transparent substrate, comprising:
irradiating light toward an upper surface of the transparent substrate;
detecting the light reflected by the light-reflective layer; and
analyzing the detected light to ascertain whether the solder bumps are normally formed in the cavities.

7. The method of claim 6, wherein analyzing the detected light comprises:
acquiring an image of the solder bumps from the detected light; and
ascertaining whether the solder bumps are normally formed in the cavities from regularities of the image.

8. The method of claim 6, wherein analyzing the detected light comprises:
acquiring an intensity profile of the detected light; and
ascertaining whether the solder bumps are normally formed in the cavities from variations in distance between peak values in the intensity profile of the detected light.
